(19) United States
(12) Patent Application Publication
(10) Pub. No.: US 2014/0318834 A1
(43) Pub. Date: Oct. 30, 2014

(54) WIRING BOARD AND METHOD FOR MANUFACTURING THE SAME

(71) Applicant: KYOCERA SLC Technologies Corporation, Yasu-shi (JP)

(72) Inventor: Tomoharu TSUCHIDA, Yasu-shi (JP)

(73) Assignee: KYOCERA SLC Technologies Corporation, Yasu-shi (JP)

(21) Appl. No.: 14/194,067

(22) Filed: May 6, 2014

(30) Foreign Application Priority Data
Feb. 28, 2013 (JP) 2013-039725

(51) Int. Cl. H05K 1/02; H05K 3/44; H05K 1/03

(52) U.S. Cl. CPC H05K 1/0271; H05K 1/0366; H05K 3/445
USPC 174/255; 29/831

(57) ABSTRACT

A wiring board of the present invention includes a core substrate in which wiring conductors are formed on both surfaces of an insulating plate, and a build-up layer in which a conductor layer is formed on a surface of an insulating resin layer having a higher coefficient of thermal expansion than that of the insulating plate. At least one build-up layer is stacked on one surface or both surfaces of the core substrate. Both surfaces of the insulating plate have different coefficients of thermal expansion. At least one build-up layer is stacked on a surface having a lower coefficient of thermal expansion. No build-up layer is stacked on the opposite surface, or a smaller number of build-up layers than that of the build-up layer formed on the surface having the lower coefficient of thermal expansion is formed on the opposite surface.

### FIELD OF INVENTION

The present invention relates to a wiring board stacked a build-up layer on at least one surface of a core substrate, and a method for manufacturing the same.

### BACKGROUND

Conventionally, as illustrated in FIG. 6, as a build-up wiring board for mounting a semiconductor element S thereon, a wiring board C stacked build-up layers 50 on one surface of a core substrate 40 is known. The core substrate 40 includes an insulating plate 41 for a core having a through hole 43, and a wiring conductor 42 for the core. The wiring conductor 42 for the core is deposited on at least part of both surfaces of the insulating plate 41 and on an inside of the through hole 43. The insulating plate 41 is formed of a glass cloth-containing insulating resin, such as a glass epoxy resin. The wiring conductors 42 on upper and lower surfaces of the insulating plate 41 are formed of copper foil and a copper plating layer. The wiring conductor 42 in the through hole 43 is formed of a copper plating layer. The through hole 43 in which the wiring conductor 42 is deposited is filled with a hole filling resin 44.

The build-up layer 50 is obtained by alternately stacking an insulating resin layer 51 and a wiring conductor 52 for the build-up. In the insulating resin layer 51, via holes 53 are formed to penetrate through the insulating resin layer 51 in positions corresponding to at least parts of the wiring conductors 42 and 52 which are disposed under the insulating resin layer 51. The insulating resin layer 51 is formed of a thermosetting resin, such as an epoxy resin. The wiring conductor 52 is formed of a copper plating layer, and is deposited on the insulating resin layer 51 and in the via holes 53. In this wiring board C, a solder resist layer 61 is deposited on the upper and lower surfaces. The solder resist layer 61 is formed of a photosensitive thermosetting resin such as an acrylic modified epoxy resin.

Such a wiring board C is formed as follows. First, as illustrated in FIG. 7A, a two-sides copper-clad plate 40P is prepared. The two-sides copper-clad plate 40P is obtained by pasting copper foil 42F on respective surfaces of the insulating resin layer 41P such as a glass epoxy plate. In general, it is possible to simultaneously manufacture hundreds to thousands of wiring boards C from one sheet of the two-sides copper-clad plate 40P. FIG. 7 illustrates only a portion corresponding to one wiring board C in order to avoid complexity.

As illustrated in FIG. 7B, the through hole 43 is formed on the two-sides copper-clad plate 40P. After the through hole 43 is formed, as illustrated in FIG. 7C, the copper plating layer 42P is deposited on the inside surface of the through hole 43 and on the surface of the copper foil 42F. As illustrated in FIG. 7D, the inside of the through hole 43 on which the copper plating layer 42P is deposited is filled with the hole filling resin 44, such as an epoxy resin, and the upper and lower surfaces are polished to be planar. At this time, the copper plating layers 42P on the upper and lower surfaces are polished and become thinner or remove.

Next, as illustrated in FIG. 7E, other copper plating layers 42P are deposited again on the upper and lower surfaces, including the upper surface of the hole filling resin 44. As illustrated in FIG. 7F, the copper foil 42F and the copper plating layers 42P on the upper and lower surfaces of the insulating plate 41 are etched into a predetermined pattern to form the wiring conductor 42. As illustrated in FIG. 7G, after the wiring conductor 42 is formed, the insulating resin layer 51 is formed only on the upper surface side of the core substrate 40. The insulating resin layer 51 is formed by stacking an uncured resin sheet of a thermosetting resin such as an epoxy resin on the upper surface of the core substrate 40, thermally curing the resin sheet, and boring the via hole 53 in a predetermined position.

Next, as illustrated in FIG. 7H, the wiring conductor 52 is formed in the via hole 53 and on the upper surface of the insulating resin layer 51. The inside of the via hole 53 is completely filled up with the wiring conductor 52. Finally, as illustrated in FIG. 7I, an insulating resin layer 51 and a wiring conductor 52 serving as a second insulating resin layer and a second wiring conductor are formed in a similar way on the insulating resin layer 51 and wiring conductor 52 serving as a first insulating resin layer and a first wiring conductor. Further, the wiring board C is obtained by forming a solder resist layer 61 on the upper surfaces of the second insulating resin layer 51 and the second wiring conductor 52 and on the lower surface of the core substrate 40. As such a conventional wiring board C, Japanese Unexamined Patent Publication No. 2004-80027 discloses a one-side stacked wiring board formed build-up layers only on one principal surface of the core substrate, for example.

However, in this conventional wiring board C, the insulating resin layer 51 of the build-up layer 50 does not contain glass cloth, while the insulating plate 41 of the core substrate 40 contains glass cloth. Therefore, a coefficient of thermal expansion of the insulating resin layer 51 is larger than a coefficient of thermal expansion of the insulating plate 41. When forming the insulating resin layer 51 on the core substrate 40, the insulating resin layer 51 suffers curing shrinkage. As a result, as illustrated in FIG. 8, the insulating resin layer 51 side will shrink more severely, and hence curvature such that the surface on the build-up layer 50 side becomes a recessed surface occurs in the wiring board C during and after manufacturing processes. Such curvature makes it difficult not only to manufacture the wiring board C but to normally mount a semiconductor device S on the wiring board C.

### SUMMARY

An object of the present invention is to provide a wiring board and a method for manufacturing the same which can suppress an generation of curvature during and after manufacturing processes, enables easier manufacture, and allows a semiconductor device S to be normally mounted.

According to one aspect, there is provided a wiring board including a core substrate configured such that both surfaces of an insulating plate are provided with wiring conductors, and a build-up layer configured such that a conductor layer is formed on a surface of an insulating resin layer having a higher coefficient of thermal expansion than that of the insulating plate, the build-up layer being arranged such that at least one build-up layer is stacked on one surface or both surfaces of the core substrate, wherein both surfaces of the insulating plate have different coefficients of thermal expansion, at least one build-up layer is stacked on a surface having a lower coefficient of thermal expansion, and the opposite surface of the insulating plate is provided with no build-up layer or a smaller number of the build-up layers than the build-up layer stacked on the surface having the lower coefficient of thermal expansion.

According to another aspect, the method including: preparing a one-side copper-clad plate obtained by pasting first copper foil on one surface of a first insulating plate, prepreg having a higher coefficient of thermal expansion after curing than that of the first insulating plate, and second copper foil; obtaining an insulating plate formed from a two-sides copper-clad plate in which the first copper foil and the second copper foil are pasted on both surfaces, by sequentially laminating the prepreg and the second copper foil on a surface opposite to the first copper foil pasting surface of the one-side copper-clad plate, and by stacking and integrating a second insulating plate and the first insulating plate by thermally curing the prepreg; forming a core substrate in which wiring conductors are formed on both surfaces of the insulating plate by etching the first copper foil and the second copper foil into a predetermined pattern; and stacking, on a first insulating plate side of the core substrate, at least one build-up layer formed of an insulating resin layer and a conductor layer, the insulating resin layer having a higher coefficient of thermal expansion than that of the first insulating plate, and stacking, on a second insulating plate side of the core substrate, no layer of the build-up layer or a smaller number of build-up layers than the number of the build-up layer stacked on the first insulating plate side.

According to the wiring board of the present invention, in the insulating plate which constitutes the core substrate, a coefficient of thermal expansion of one surface side having a larger number of build-up layers thereon is smaller than that of the opposite surface side. Therefore, even when the core substrate is to curve toward the surface side having a larger number of build-up layers thereon due to shrinkage of the build-up layers, generation of curvature is suppressed by a shrinking force of the opposite surface side having a higher coefficient of thermal expansion. Accordingly, a wiring board having a smaller curvature can be obtained.

Also, when the prepreg undergoes thermal curing, the prepreg is cured to shrink, and a curving force is generated which curves the core substrate such that a second surface side becomes a recessed surface. Therefore, according to the method for manufacturing the wiring board of the present invention, the build-up layer is formed so that a larger number of layers are formed on the first insulating plate side of the core substrate. Therefore, since a curving force that is exerted to curve the core substrate by the build-up layer is offset by a curving force that the thermally cured prepreg exerts to curve the core substrate, it is possible to effectively prevent the wiring board from being seriously curved during and after manufacturing processes.

### BRIEF DESCRIPTION OF THE DRAWINGS

FIG. 1 is a schematic cross-sectional view illustrating one embodiment of a wiring board according to the present invention.

FIGS. 2A to 2I are schematic cross-sectional views describing one embodiment of a manufacturing method for the wiring board illustrated in FIG. 1.

FIGS. 3A and 3B are schematic cross-sectional views describing one embodiment of a manufacturing method for a two-sides copper-clad plate illustrated in FIG. 2A.

FIG. 4 is a schematic cross-sectional view describing a shrinking force in the wiring board illustrated in FIG. 1.

FIG. 5 is a schematic cross-sectional view illustrating another embodiment of a wiring board according to the present invention.

FIG. 6 is a cross-sectional view illustrating an example of a conventional wiring board.

FIGS. 7A to 7I are schematic cross-sectional views describing a method for manufacturing the wiring board illustrated in FIG. 6.

FIG. 8 is a schematic cross-sectional view describing a shrinking force in the wiring board illustrated in FIG. 6.

### DETAILED DESCRIPTION OF THE PREFERRED EMBODIMENTS

One embodiment of a wiring board according to the present invention will be described based on FIG. 1. A wiring board A illustrated in FIG. 1 is stacked a build-up layer 20 on only one surface side of a core substrate 10. A semiconductor device S is mounted on the build-up layer 20. The core substrate 10 is configured in such a manner that a wiring conductor 12 is deposited on both surfaces of an insulating plate 11 having through holes 13 and in the through holes 13. The insulating plate 11 is formed of a first insulating plate 11a and a second insulating plate 11b which are made of a glass cloth-containing insulating resin, such as a glass epoxy resin, for example. The insulating plate 11 has a thickness of about 100 to 800 μm, preferably about 150 to 500 μm, and more preferably about 200 to 500 μm. Although the insulating plate 11 illustrated in FIG. 1 has a double-layer structure including the first insulating plate 11a and the second insulating plate 11b, the insulating plate 11 may be a laminate structure including three or more layers.

When the insulating plate 11 has a laminate structure including three or more layers, one surface may be provided by the first insulating plate 11a and the other surface may be provided by the second insulating plate 11b. A diameter of the through hole 13 is about 50 to 250 μm. The wiring conductors 12 are formed on upper and lower surfaces of the insulating plate 11 by copper foil and a copper plating layer. The wiring conductor 12 in the through holes 13 is formed of a copper plating layer. The wiring conductor 12 has a thickness of about 5 to 25 μm. The through holes 13 in which the wiring conductor 12 is deposited are filled with a hole filling resin 14. Examples of the hole filling resin 14 include thermosetting resins, such as an epoxy resin.

The build-up layer 20 is obtained by alternately stacking insulating resin layers 21 and conductor layers 22. In the wiring board A of FIG. 1, although the build-up layer 20 having two layers is formed, at least one build-up layer may be formed in the wiring board of the present invention. The insulating resin layer 21 is formed of a thermosetting resins, such as an epoxy resin, and has a higher coefficient of thermal expansion than that of the first insulating plate 11a. The insulating resin layer 21 has a thickness of about 15 to 50 μm, preferably about 20 to 50 μm, and more preferably about 20 to 40 μm. The insulating resin layer 21 has via holes 23 extending to the wiring conductor 12 or the conductor layer 22 formed underneath. The via hole 23 has a diameter of about 30 to 100 μm. A coefficient of thermal expansion of the insulating resin layer 21 is, in a temperature range of from room temperature to the glass transition point of a resin material, preferably 5 to 50 ppm/° C. and more preferably 15 to 50 ppm/° C., and is preferably higher than that of the first insulating plate 11a by 1.5 to 45 ppm/° C., and more preferably by 3 to 45 ppm/° C. The conductor layer 22 is deposited on the insulating resin layer 21 and in the via holes 23. The conductor layer 22 is formed of a copper plating layer. The inside of the via hole 23 is completely filled with the conductor layer 22, and has a thickness of about 5 to 25 μm on the insulating resin layer 21. In this wiring board A, a solder resist layer 31 is also stacked on the upper and lower surfaces thereof. The solder resist layer 31 is formed of a photosensitive thermosetting resins, such as an acrylic modified epoxy resin. The solder resist layer 31 has a thickness of about 5 to 30 μm and more preferably about 10 to 30 μm.

In addition, in the wiring board A, the coefficient of thermal expansion of the insulating plate 11 on a side on which the build-up layer 20 is stacked is smaller than the coefficient of thermal expansion of the opposite side. For example, a first glass cloth-containing insulating resin layer (first insulating plate) 11a having a low coefficient of thermal expansion and a second glass cloth-containing insulating resin layer (second insulating plate) 11b having a higher coefficient of thermal expansion than that of the first insulating resin plate are stacked and integrated to form the insulating plate 11. Therefore, as illustrated in FIG. 4, even though the core substrate 10 is to curve due to shrinkage of the insulating resin layer 21 constituting the build-up layer 20, generation of curvature is suppressed by a shrinking force of the second glass cloth-containing insulating resin layer 11b which is on the opposite surface side and has a large coefficient of thermal expansion. Therefore, the wiring board having a small curvature can be obtained.

In order to make the coefficient of thermal expansion of the second glass cloth-containing insulating resin layer 11b higher than that of the first glass cloth-containing insulating resin layer 11a, a ratio of the glass cloth to the second glass cloth-containing insulating resin layer 11b is made to be lower than a ratio of the glass cloth to the first glass cloth-containing insulating resin layer 11a, for example. In this case, as a content of a resin component in the second glass cloth-containing insulating resin layer 11b increases, the coefficient of thermal expansion of the second glass cloth-containing insulating resin layer 11b correspondingly increases. Alternatively, as glass cloth in the second glass cloth-containing insulating resin layer 11b, glass cloth which has a higher coefficient of thermal expansion than that of the glass cloth in the first glass cloth-containing insulating resin layer 11a can be used.

The coefficient of thermal expansion of the first glass cloth-containing insulating resin layer 11a is preferably 1 to 20 ppm/° C. and more preferably 1.5 to 20 ppm/° C. within a temperature range of from room temperature to the glass transition point of a resin material. The coefficient of thermal expansion of the second glass cloth-containing insulating resin layer 11b is preferably 4 to 25 ppm/° C. within a temperature range of from room temperature to the glass transition point of a resin material, and is preferably 2 to 5 ppm/° C. and more preferably 3 to 5 ppm/° C. higher than the coefficient of thermal expansion of the first glass cloth-containing insulating resin layer 11a.

The first glass cloth-containing insulating resin layer 11a preferably has a thickness of about 100 to 300 μm, and the second glass cloth-containing insulating resin layer 11b preferably has a thickness of about 50 to 150 μm. Further, the thickness of the second glass cloth-containing insulating resin layer 11b is preferably thinner than the thickness of the first glass cloth-containing insulating resin layer 11a by 50 to 200 μm, and more preferably by 50 to 150 μm.

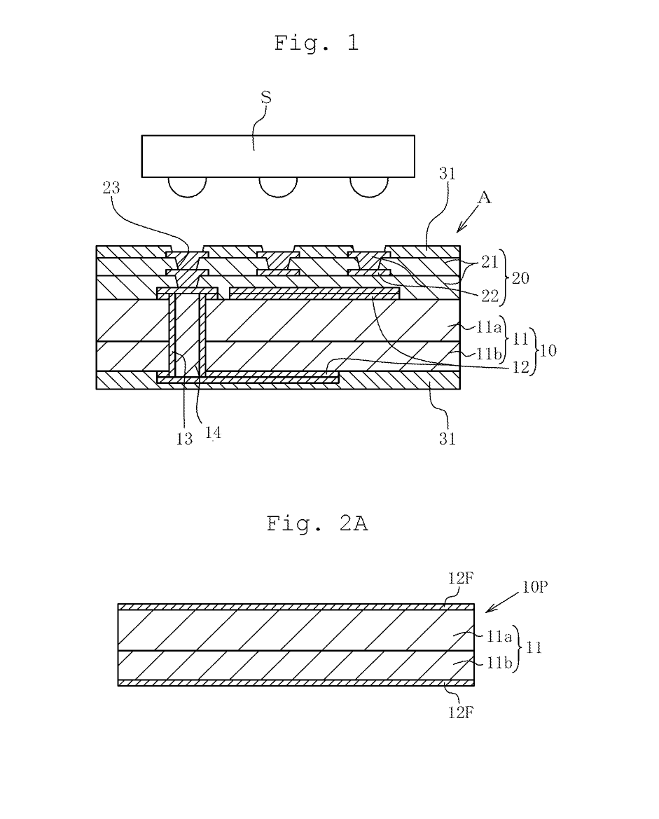

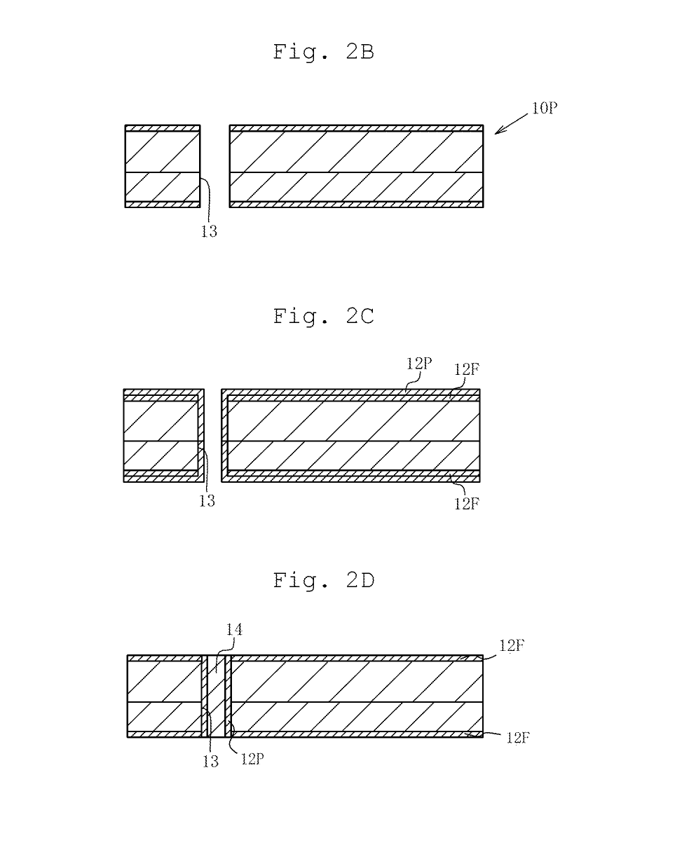

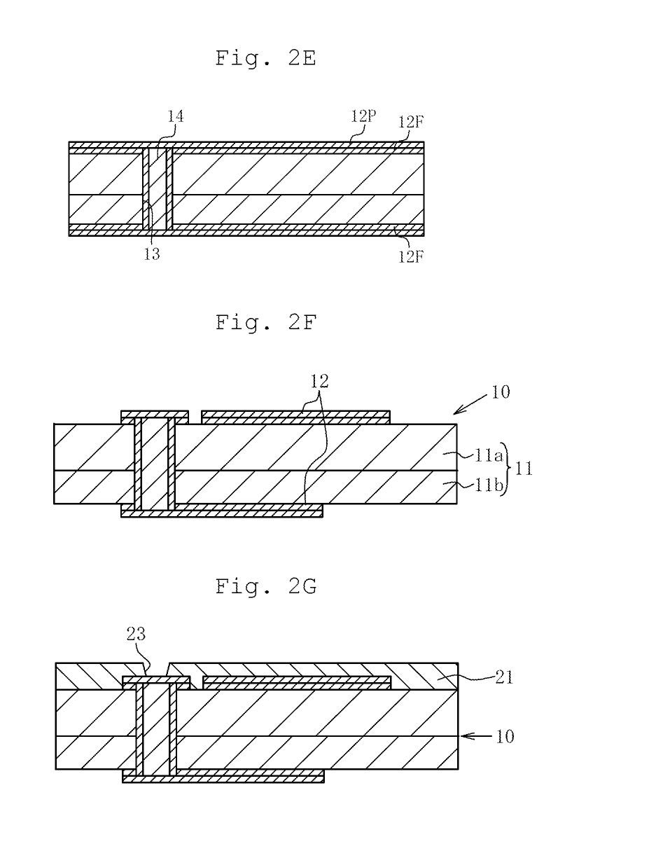

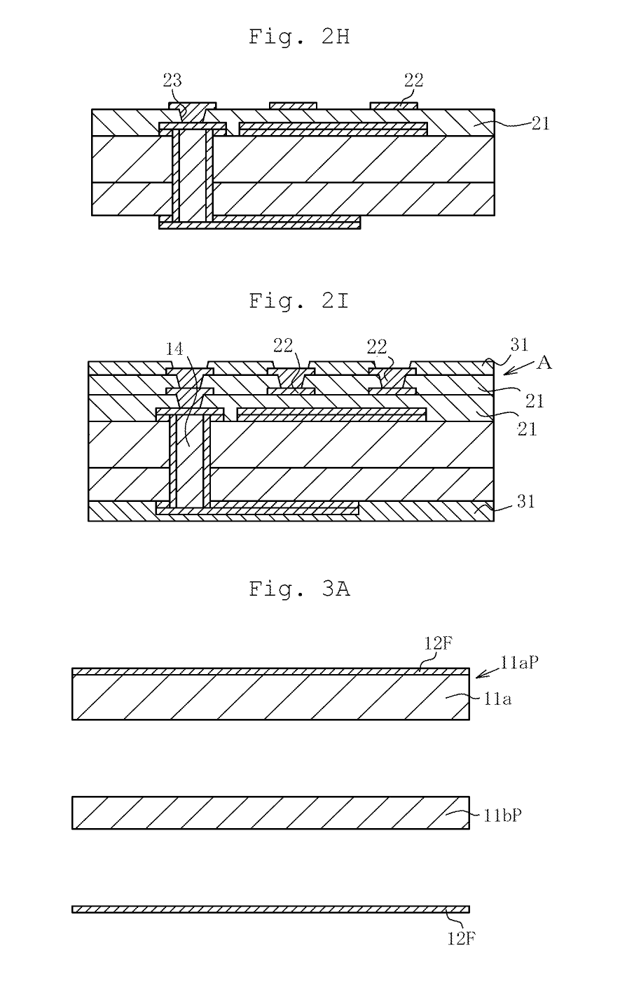

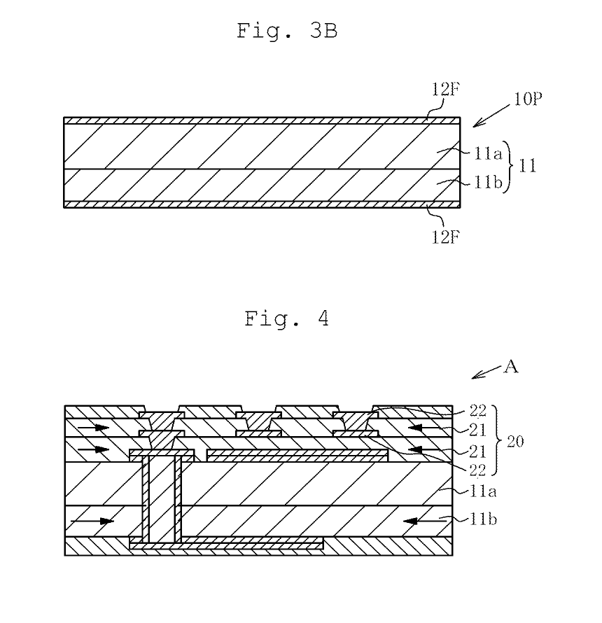

Next, one embodiment of a method for manufacturing the above-described wiring board A will be described based on FIGS. 2 and 3. The same reference characters will refer to the same parts of the wiring board A, and the detailed description on those parts will be omitted.

As illustrated in FIG. 2A, a two-sides copper-clad plate 10P is prepared. The two-sides copper-clad plate 10P is configured such that copper foil 12F is pasted on both surfaces of an insulating plate 11 formed by stacking and integrating a first glass cloth-containing insulating resin layer 11a and a second glass cloth-containing insulating resin layer 11b. As described above, a coefficient of thermal expansion of the second glass cloth-containing insulating resin layer 11b is made to be higher than a coefficient of thermal expansion of the first glass cloth-containing insulating resin layer 11a. Since the coefficients of thermal expansion and thicknesses of the first glass cloth-containing insulating resin layer 11a and the second glass cloth-containing insulating resin layer 11b are as described above, a description thereof will be omitted.

The copper foil 12F has a thickness of about 5 to 25 μm. The two-sides copper-clad plate 10P has about 500 to 600 mm in width and length. Several hundreds to thousands of the wiring boards A can be manufactured simultaneously from one sheet of the two-sides copper-clad plate 10P. In order to avoid complexity, only a portion corresponding to one wiring board A is illustrated in FIG. 2.

Here, a method for forming such a two-sides copper-clad plate 10P will be described based on FIG. 3. As illustrated in FIG. 3A, a one-side copper-clad plate 11aP pasted one sheet of copper foil 12F on only one surface of a first glass cloth-containing insulating resin layer 11a, prepreg 11bP used as a second glass cloth-containing insulating resin layer 11b, and another sheet of copper foil 12F are prepared. The one-side copper-clad plate 11aP is formed by, for example, performing etching-removal on the copper foil 12F formed on one surface of the two-sides copper-clad plate pasted the copper foil 12F on both surfaces of the first glass cloth-containing insulating resin layer 11a. A ratio of glass cloth in the prepreg 11bP is set to be smaller than a ratio of glass cloth in the first glass cloth-containing insulating resin layer 11a. Alternatively, a coefficient of thermal expansion of the glass cloth in the prepreg 11bP is set to be higher than a coefficient of thermal expansion of the glass cloth in the first glass cloth-containing insulating resin layer 11a.

As illustrated in FIG. 3A, the prepreg 11bP and another sheet of the copper foil 12F are sequentially laminated on one surface opposite to the one sheet of the copper foil 12F pasting surface of the one-side copper-clad plate 11aP, and the prepreg 11bP is heated and pressed from upper and lower sides to be thermally cured. Thus, as illustrated in FIG. 3B, the first glass cloth-containing insulating resin layer 11a and the second glass cloth-containing insulating resin layer 11b obtained by being thermally cured prepreg 11bP are stacked and integrated, and the two-sides copper-clad plate 10P which has the copper foil 12F pasted on both surfaces thereof is formed. At this time, the force which occurs when the prepreg 11bP is cured to shrink and the force of thermal shrinkage which occurs when temperature returns from a thermal curing temperature to room temperature are added to the two-sides copper-clad plate 10P, which generates a stress that is exerted to curve the second glass cloth-containing insulating resin layer 11b into a recessed surface.

Next, as illustrated in FIG. 2B, through holes 13 are formed in the two-sides copper-clad plate 10P. The through hole 13 has a diameter of about 50 to 250 μm as described above. Drilling or laser processing is employed to form the through holes 13. Alternatively, the through holes 13 may be formed by a sandblast method. As illustrated in FIG. 2C, a copper plating layer 12P is deposited in the through holes 13 and on the surface of the copper foil 12F. The copper plating layer 12P is deposited by sequentially performing electroless copper plating and electrolytic copper plating. The electroless copper plating produces a thickness of about 0.1 to 0.5 μm, and the electrolytic copper plating produces a thickness of about 5 to 25 μm.

As illustrated in FIG. 2D, the inside of the through holes 13 deposited the copper plating layer 12P are filled up with a hole filling resin 14, and upper and lower surfaces are polished to be planar. At this time, the copper plating layers 12P on the upper and lower surfaces are polished and become thinner or remove. A belt polishing device or a roll polishing device is used for the polishing. A thermosetting resin, such as an epoxy resin, is used as the hole filling resin 14.

As illustrated in FIG. 2E, the copper plating layer 12P is again deposited on the upper and lower surfaces, including on the hole filling resin 14. The copper plating layer 12P is deposited by sequentially performing electroless copper plating and electrolytic copper plating in the same way as the above-described case. The thicknesses in the electroless copper plating and the electrolytic copper plating are almost the same as the above-described case. Then, as illustrated in FIG. 2F, the copper foil 12F and the copper plating layer 12P on the upper and lower surfaces of the insulating plate 11 are etched into a predetermined pattern, and thus the wiring conductor 12 is formed. A well-known subtractive process is employed for the etching.

As illustrated in FIG. 2G, the insulating resin layer 21 is formed only on the upper surface side of the core substrate 10. The insulating resin layer 21 is formed by stacking and thermally curing an uncured resin sheet of a thermosetting resin, such as an epoxy resin, on the upper surface of the core substrate 10 and by boring via holes 23 in predetermined positions. A vacuum press is employed to stack the uncured resin sheet. Laser processing is employed for the boring of the via holes 23. The thickness and coefficient of thermal expansion of the insulating resin layer 21 and the diameter of the via hole are the same as described above, and a description thereof will be omitted.

As illustrated in FIG. 2H, a conductor layer 22 is formed in the via holes 23 and on the upper surface of the insulating resin layer 21. The inside of the via holes 23 are completely filled up with the conductor layer 22. The thickness of the conductor layer 22 on the insulating resin layer 21 is as described above, and a description thereof will be omitted. The conductor layer 22 is formed through electroless copper plating and electrolytic copper plating, and is formed into a predetermined pattern employing a well-known semiadditive process.

Finally, as illustrated in FIG. 2I, a second insulating resin layer 21 and a second conductor layer 22 are formed on the first insulating resin layer 21 and the first conductor layer 22 using a similar method. Further, a wiring board A is obtained by forming a solder resist layer 31 on upper surfaces of the second insulating resin layer 21 and the second conductor layer 22 and on the lower surface of the core substrate 10.

At this time, as illustrated in FIG. 4, even though the core substrate 10 is to curve due to shrinkage of the insulating resin layer 21 constituting the build-up layer 20, since generating of curvature is suppressed by a shrinking force of the second glass cloth-containing insulating resin layer 11b having a higher coefficient of thermal expansion formed on the opposite surface side, a wiring board of a small curvature can be obtained. Therefore, according to the wiring board and the method for manufacturing the same of the present invention, the wiring board which is less likely to suffer from curvature during and after manufacturing processes, which can be easily manufactured, and which can normally mount a semiconductor device thereon can be obtained.

Further, according to the present invention, since the curvature is less likely to occur during and after manufacturing processes, the through holes and the via holes formed in the insulating plate 11 and the build-up layer 20 are less likely to be misaligned. As a result, an accurate interlayer electric connection is obtained, and thus the reliability of the wiring board can be improved.

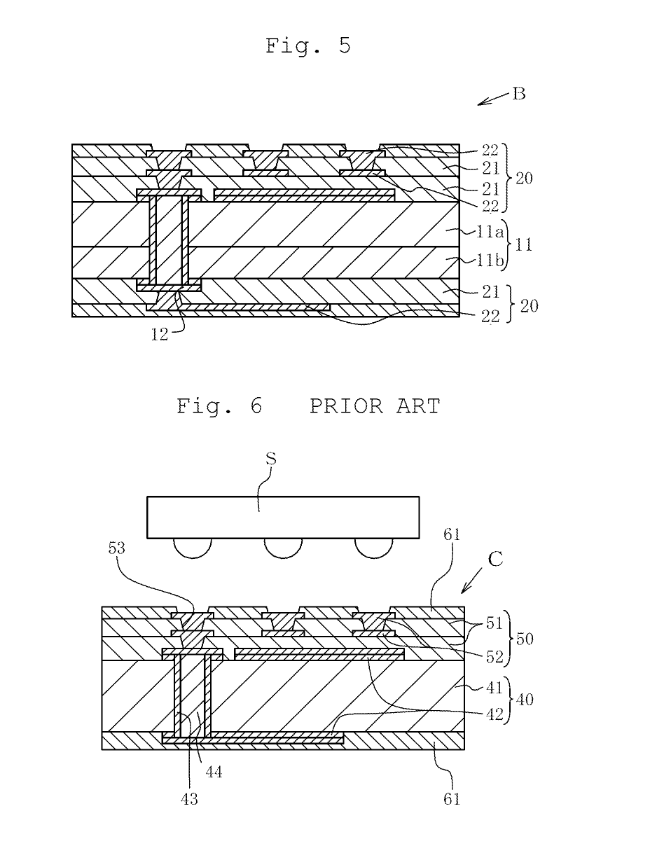

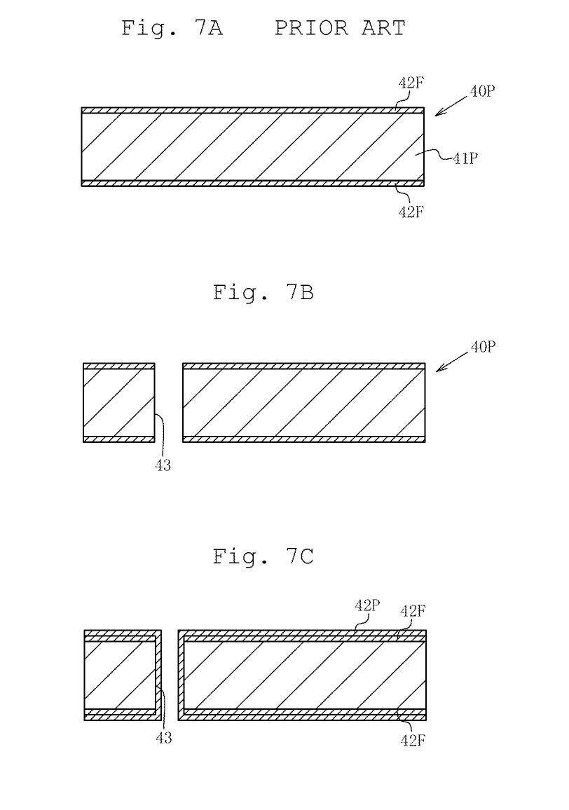

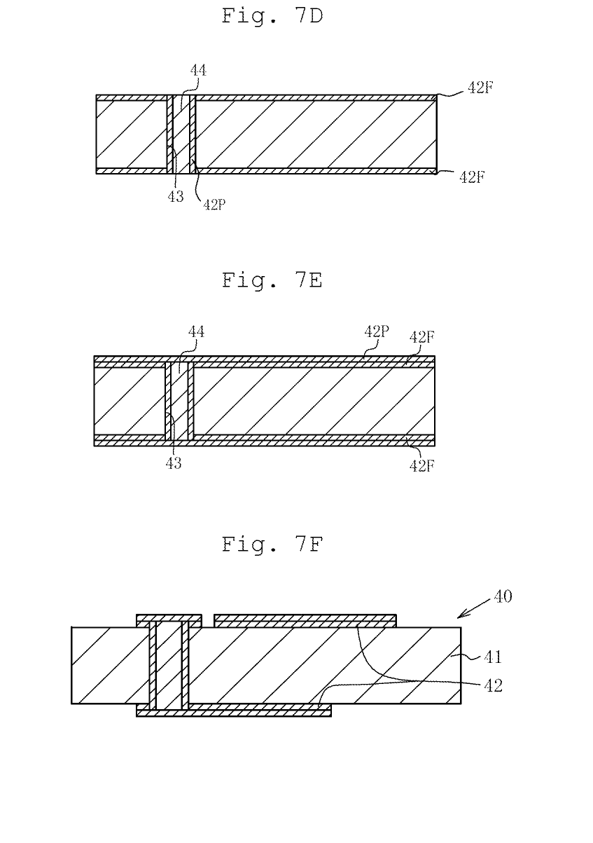

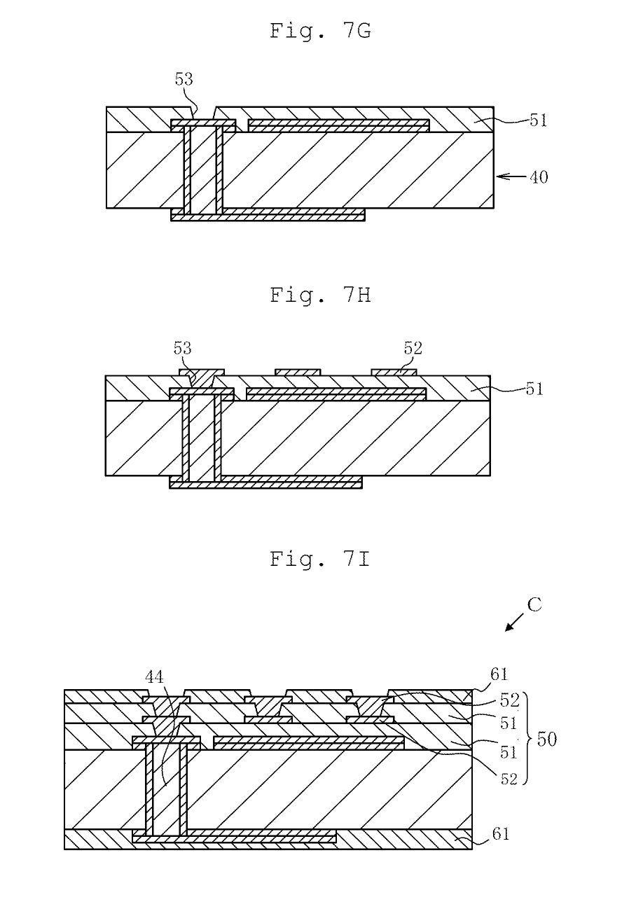

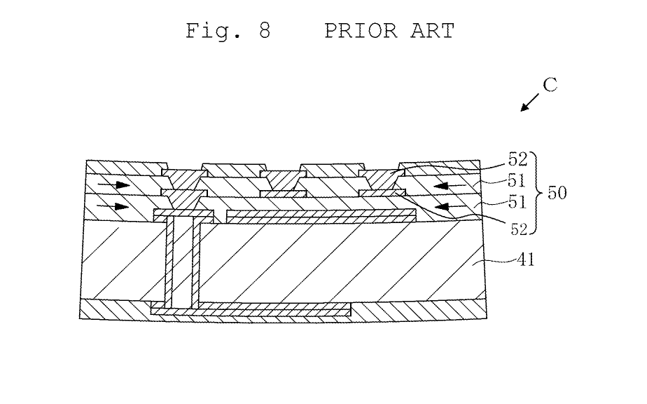

A wiring board and a method for manufacturing the same of the present invention are not limited to the above-described embodiments, and various changes are possible, without departing from the spirit of the present invention. For example, although one embodiment described above has illustrated an example in which build-up layers 20 are formed on only one surface of a core substrate 10, the present invention may also apply to an example in which different numbers of build-up layers 20 are formed on both surfaces of core substrate 10, respectively, like the wiring board B illustrated in FIG. 5. In this case, the number of build-up layers 20 stacked on the first insulating plate (first glass cloth-containing insulating resin layer) 11a side can be set to be larger than the number of build-up layers 20 stacked on the second insulating plate (second glass cloth-containing insulating resin layer) 11b side.

1. A wiring board comprising:
a core substrate configured such that both surfaces of an insulating plate are provided with a wiring conductor; and
a build-up layer configured such that a conductor layer is formed on a surface of an insulating resin layer having a higher coefficient of thermal expansion than that of the insulating plate, the build-up layer being arranged such that at least one build-up layer is stacked on one surface or both surfaces of the core substrate, wherein
both surfaces of the insulating plate have different coefficients of thermal expansion,
one of the surfaces having a lower coefficient of thermal expansion is provided with at least one build-up layer stacked thereon, and
the opposite surface is provided with no build-up layer or a smaller number of build-up layers stacked thereon than the number of the build-up layer stacked on the surface having the lower coefficient of thermal expansion.

2. The wiring board according to claim 1, wherein
the insulating plate has a laminate structure including a plurality of layers,
one surface of the laminate is provided by a first insulating plate, and
the other surface of the laminate is provided by a second insulating plate having a higher coefficient of thermal expansion than that of the first insulating plate.

3. The wiring board according to claim 2, wherein at least one of the first insulating plate and the second insulating plate is made of an insulating resin layer containing glass cloth.

4. The wiring board according to claim 2, wherein the second insulating plate has a higher coefficient of thermal expansion than that of the first insulating plate by 2 to 5 ppm/° C.

5. The wiring board according to claim 2, wherein
the first insulating plate has a coefficient of thermal expansion of 1 to 20 ppm/° C. within a temperature range of from room temperature to a glass transition point, and
the second insulating plate has a coefficient of thermal expansion of 4 to 25 ppm/° C. within a temperature range of from the room temperature to the glass transition point.

6. The wiring board according to claim 2, wherein a thickness of the second insulating plate is thinner than a thickness of the first insulating plate by 50 to 200 μm.

7. The wiring board according to claim 2, wherein the first insulating plate has a thickness of 100 to 300 μm, and the second insulating plate has a thickness of 50 to 150 μm.

8. The wiring board according to claim 2, wherein
the insulating plate has a through hole,
the wiring conductor is formed on an inside circumferential surface of the through hole, and
an inside of the through hole is filled with a resin.

9. The wiring board according to claim 8, wherein the insulating resin layer of the build-up layer has a via hole, and
the via hole is filled with a conductor that forms a conductor layer so that the conductor is electrically connected to the wiring conductor formed in the through hole or a conductor layer formed on an other insulating resin layer.

10. A method for manufacturing a wiring board, the method comprising:
preparing a one-side copper-clad plate obtained by pasting a first copper foil on one surface of a first insulating plate, a prepreg having a higher coefficient of thermal expansion after curing than a coefficient of thermal expansion of the first insulating plate, and a second copper foil;
obtaining an insulating plate formed from a two-sided copper-clad plate in which the first copper foil and the second copper foil are pasted on both surfaces; by sequentially laminating the prepreg and the second copper foil on a surface opposite to the first copper foil pasting surface of the one-side copper-clad plate, and by stacking and integrating a second insulating plate and the first insulating plate by thermally curing the prepreg;
forming a core substrate in which wiring conductors are formed on both surfaces of the insulating plate; by etching the first copper foil and second copper foil into a predetermined pattern; and
stacking, on a first insulating plate side of the core substrate, at least one build-up layer formed of an insulating resin layer and a conductor layer, the insulating resin layer having a higher coefficient of thermal expansion than that of the first insulating plate, and stacking, on a second insulating plate side of the core substrate, no build-up layer or a smaller number of the build-up layers than that of the build-up layer stacked on the first insulating plate side.

11. The method for manufacturing the wiring board according to claim 10, further comprising:
forming a through hole in the insulating plate after obtaining the insulating plate; and
forming the wiring conductor on an inside circumferential surface of the through hole, and filling the through hole with a resin.

12. The method for manufacturing the wiring board according to claim 11, further comprising:
forming a via hole in the insulating resin layer in the stacking of the build-up layer, and filling the via hole with a conductor that forms a conductor layer so that the conductor layer is electrically connected to a wiring conductor formed in the through hole or a conductor layer formed on an other insulating resin layer.
